(19) United States
(12) Patent Application Publication
(10) Pub. No.: US 2020/0057580 A1
(43) Pub. Date: Feb. 20, 2020

(54) SEMICONDUCTOR MEMORY DEVICE AND OPERATING METHOD THEREOF

(71) Applicant: SK hynix Inc., Gyeonggi-do (KR)

(72) Inventors: Young Gyun KIM, Seoul (KR); Hyun Woo LEE, Gyeonggi-do (KR)

(21) Appl. No.: 16/298,604

(22) Filed: Mar. 11, 2019

(30) Foreign Application Priority Data
Aug. 16, 2018 (KR) 10-2018-0095752

(51) Int. Cl. G06F 3/06; G11C 16/10; G11C 16/14

(52) U.S. Cl. CPC G06F 3/0659; G11C 16/10; G11C 16/14; G11C 16/0483; G06F 3/0653; G06F 3/0679; G06F 3/0604

(57) ABSTRACT

A semiconductor memory device includes a memory cell array, a peripheral circuit, a control logic, and a temperature sensor. The memory cell array includes a plurality of memory cells. The peripheral circuit performs an operation on the memory cell array. The control logic controls an operation of the peripheral circuit, and generates a ready-busy signal representing whether the operation of the peripheral circuit is completed. The temperature sensor measures a temperature of the semiconductor memory device. The control logic generates the ready-busy signal, based on the temperature.

### CROSS-REFERENCE TO RELATED APPLICATION

The present application claims priority under 35 U.S.C. § 119(a) to Korean patent application number 10-2018-0095752, filed on Aug. 16, 2018, the disclosure of which is incorporated herein by reference in its entirety.

### BACKGROUND

### Field of Invention

The present disclosure generally relates to an electronic device. Particularly, the disclosure relates to a semiconductor memory device and an operating method thereof.

### Description of Related Art

Memory devices may be formed in a two-dimensional structure in which strings are arranged horizontally with respect to a semiconductor substrate, or be formed in a three-dimensional structure in which strings are arranged vertically with respect to a semiconductor substrate. A three-dimensional semiconductor device is a memory device formed to overcome the degree of integration limitation of the two-dimensional semiconductor devices, and may include a plurality of memory cells vertically stacked on a semiconductor substrate.

### SUMMARY

Embodiments provide a semiconductor memory device having improved reliability and an operating method thereof.

According to an aspect of the present disclosure, there is provided a semiconductor memory device including: a memory cell array including a plurality of memory cells; a peripheral circuit configured to perform an operation on the memory cell array; a control logic configured to control an operation of the peripheral circuit, and generate a ready-busy signal representing whether the operation of the peripheral circuit is completed; and a temperature sensor configured to measure a temperature of the semiconductor memory device, wherein the control logic generates the ready-busy signal, based on the temperature.

When the temperature is higher than a predetermined reference temperature, the control logic may provide a dummy busy time generate the ready-busy signal.

The control logic may maintain a busy state of the ready-busy signal during the dummy busy time after the operation of the peripheral circuit is completed.

The control logic may include a ready-busy signal generator The ready-busy signal generator may have: a reference temperature storage configured to the reference temperature; a dummy busy determiner configured to generate a dummy busy activation signal by comparing the temperature and the reference temperature; and a signal generator configured to generate the ready-busy signal, based on the dummy busy activation signal.

The dummy busy determiner may enable the dummy busy activation signal when the temperature is higher than the reference temperature, and disable the dummy busy activation signal when the temperature is equal to or lower than the reference temperature.

The signal generator may change, when the dummy busy activation signal is enabled, the state of the ready-busy signal to a ready state after the signal generator stands by for the dummy busy time from the time at which the operation of the peripheral circuit is completed.

The signal generator may change, when the dummy busy activation signal is disabled, the state of the ready-busy signal to the ready state at the time at which the operation of the peripheral circuit is completed.

The control logic may include a ready-busy signal generator. The ready-busy signal generator may include: a reference temperature storage configured to store a dummy busy table including a plurality of reference temperature ranges and respectively corresponding dummy busy times; a dummy busy determiner configured to generate a dummy busy activation signal by comparing the temperature with the dummy busy table; and a signal generator configured to generate the ready-busy signal, based on the dummy busy activation signal.

According to another aspect of the present disclosure, there is provided a method for operating a semiconductor memory device, the method including: receiving an operation command from a controller; performing an operation corresponding to the received operation command; and controlling a ready-busy signal output from the semiconductor memory device to the controller according to a temperature of the semiconductor memory device.

The ready-busy signal may maintain a busy state during the operation.

The controlling of the ready-busy signal may include: checking a temperature of the semiconductor memory device; comparing the temperature with a predetermined reference temperature; and controlling the ready-busy signal, based on the comparison result.

The controlling of the ready-busy signal, based on the comparison result, may include: standing by, when the temperature is higher than the reference temperature, for a predetermined dummy busy time; and changing the state of the ready-busy signal from the busy state to a ready state after the predetermined dummy busy time.

The controlling of the ready-busy signal, based on the comparison result, may include changing, when the temperature is equal to or lower than the reference temperature, the state of the ready-busy signal from the busy state to the ready state.

The controlling of the ready-busy signal may include: checking a temperature of the semiconductor memory device; comparing the temperature with a predetermined dummy busy table; and controlling the ready-busy signal, based on the comparison result.

The dummy busy table may include a plurality of reference temperature ranges and respectively corresponding dummy busy times.

The controlling of the ready-busy signal based on the comparison result may include changing the state of the ready-busy signal from the busy state to the ready state after a dummy busy time corresponding to a reference temperature section to which the temperature of the semiconductor memory device belongs.

The operation command may be program command.

The operation command may be an erase command.

According to another aspect of the present disclosure, there is provided a memory device for performing a data operation in response to a command from a controller, the memory device comprising: a sensor configured to measure a temperature of the memory device during the data operation; and a control logic configured to provide the controller with a busy signal during the data operation and with a ready signal upon completion of the data operation, wherein the control logic provides, when the temperature is higher than a threshold, the controller with the busy signal instead of the ready signal for a predetermined time even after the completion.

### BRIEF DESCRIPTION OF THE DRAWINGS

Various exemplary embodiments of the present invention will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the example embodiments to those skilled in the art.

In the drawings, dimensions of the figures may be exaggerated for clarity. It will be understood that when an element is referred to as being “between” two elements, it can be the only element between the two elements, or one or more intervening elements may also be present. Like reference numerals refer to like elements throughout.

FIG. 1 is a block diagram illustrating a memory system including a semiconductor memory device and a controller.

FIG. 2 is a block diagram illustrating a structure of the semiconductor memory device of FIG. 1.

FIG. 3 is a diagram illustrating an embodiment of a memory cell array of FIG. 2.

FIG. 4 is a diagram illustrating an embodiment of the memory cell array of FIG. 2.

FIG. 5 is a diagram illustrating an embodiment of the memory cell array of FIG. 2.

FIG. 6 is a diagram illustrating a pin configuration of the semiconductor memory device.

FIG. 7 is a block diagram illustrating an exemplary embodiment of a ready-busy signal generator of FIG. 2.

FIGS. 8A and 8B are timing diagrams illustrating an operation of the semiconductor memory device according to an embodiment of the present disclosure.

FIG. 9 is a flowchart illustrating an operating method of the semiconductor memory device according to another embodiment of the present disclosure.

FIG. 10 is a flowchart illustrating an embodiment of a step of FIG. 9.

FIG. 11 is a flowchart illustrating an embodiment of a step of FIG. 9.

FIG. 12 is a diagram illustrating an exemplary embodiment of a dummy busy table.

FIG. 13 is a block diagram illustrating a memory system including the semiconductor memory device of FIG. 2.

FIG. 14 is a block diagram illustrating an application example of the memory system of FIG. 13.

FIG. 15 is a block diagram illustrating a computing system including the memory system described with reference to FIG. 14.

### DETAILED DESCRIPTION

In the present disclosure, advantages, features and methods for achieving them will become more apparent after a reading of the following exemplary embodiments taken in conjunction with the drawings. The present disclosure may, however, be embodied in different forms and should not be construed as being limited to the embodiments set forth herein. Rather, these embodiments are provided to describe the present disclosure in detail to the extent that those skilled in the art to which the disclosure pertains may easily enforce the technical concept of the present disclosure. It is noted that reference to “an embodiment” does not necessarily mean only one embodiment, and different references to “an embodiment” are not necessarily to the same embodiment(s).

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present invention.

As used herein, singular forms may include the plural forms as well and vice versa, unless the context clearly indicates otherwise.

It will be further understood that the terms “comprises,” “comprising,” “includes,” and “including” when used in this specification, specify the presence of the stated elements and do not preclude the presence or addition of one or more other elements. As used herein, the term “and/or” includes any and all combinations of one or more of the associated listed items.

In the entire specification, when an element is referred to as being “connected” or “coupled” to another element, it can be directly connected or coupled to the another element or be indirectly connected or coupled to the another element with one or more intervening elements interposed therebetween. In addition, when an element is referred to as “including” a component, this indicates that the element may further include another component instead of excluding another component unless there is different disclosure.

Hereinafter, exemplary embodiments of the present disclosure will be described in detail with reference to the accompanying drawings. The same reference numerals are used to designate the same elements as those shown in other drawings. In the following descriptions, only portions necessary for understanding operations according to the to exemplary embodiments may be described, and descriptions of the other portions may be omitted so as to not obscure important concepts of the embodiments.

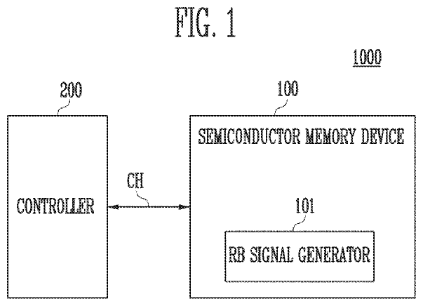

FIG. 1 is a block diagram illustrating a memory system 1000 including a semiconductor memory device 100 and a controller 200.

Referring to FIG. 1, the memory system 1000 includes the semiconductor memory device 100 and the controller 200.

The semiconductor memory device 100 operates under the control of the controller 200. The semiconductor memory device 100 includes a memory cell array having a plurality of memory blocks. In an embodiment, the semiconductor memory device 100 may be a flash memory device.

The semiconductor memory device 100 receives a command and an address from the controller 200 through a channel CH, and accesses an area selected by the address in the memory cell array. That is, the semiconductor memory device 100 performs an internal operation corresponding to the command on the area selected by the address.

For example, the semiconductor memory device 100 may perform a program operation, a read operation, and an erase operation. In the program operation, the semiconductor memory device 100 may program data in the area selected by the address. In the read operation, the semiconductor memory device 100 may read data from the area selected by the address. In the erase operation, the semiconductor memory device 100 may erase data stored in the area selected by the address.

The semiconductor memory device 100 includes a ready-busy (RB) signal generator 101. The ready-busy signal generator 101 outputs a ready-busy signal representing whether the semiconductor memory device 100 corresponds to a ready state or busy state.

When the semiconductor memory device 100 is in the ready state, it may mean that the semiconductor memory device 100 has completed an internal operation and is standing by. For example, when the semiconductor memory device 100 is in the ready state, it may mean that the semiconductor memory device 100 has completed a program, read or erase operation corresponding to a current command and is ready for serving a next command to be provided thereto. In the ready state, the ready-busy signal becomes the ready state.

When the semiconductor memory device 100 is in the busy state, it may mean that the semiconductor memory device 100 is still performing the internal operation. For example, when the semiconductor memory device 100 is in the busy state, it may mean that the semiconductor memory device 100 is still performing the program, read or erase operation corresponding to a current command and is not yet ready for serving a next command to be provided thereto. In the busy state, the ready-busy signal becomes the “busy state.”

The ready-busy signal generator 101 of the semiconductor memory device 100 according to the embodiment of the present disclosure controls, regardless of the actual state of the semiconductor memory device 100, a time at which the state of the ready-busy signal is changed from the busy state to the ready state according to an internal temperature of the semiconductor memory device 100. Thus, when the temperature of the semiconductor memory device 100 increases, an operation can be performed to cope with the increased temperature without control of the controller 200.

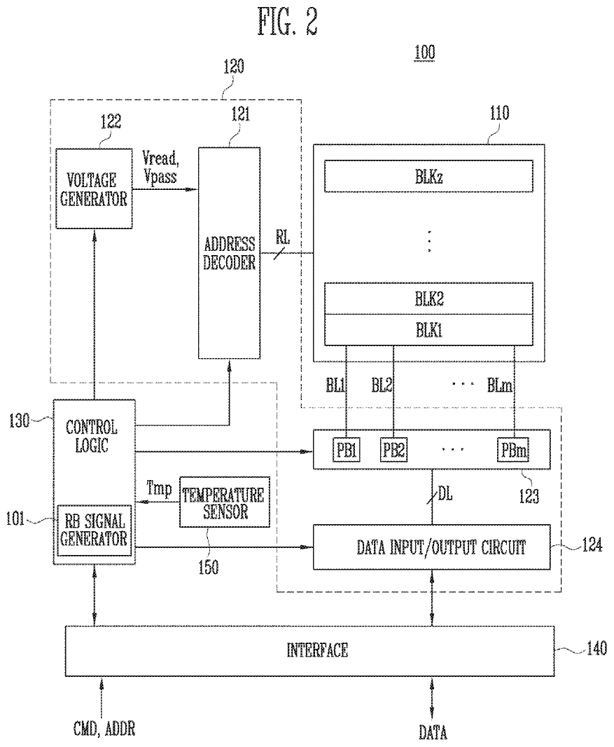

FIG. 2 is a block diagram illustrating a structure of the semiconductor memory device 100 of FIG. 1.

Referring to FIG. 2, the semiconductor memory device 100 may include a memory cell array 110, a peripheral circuit 120, a control logic 130, an interface 140, and a temperature sensor 150.

The memory cell array 110 may be coupled to an address decoder 121 through source select lines SSL, word lines WL, and drain select lines DSL, and be coupled to a read/write circuit 123 through bit lines BL.

The memory cell array 110 includes a plurality of memory blocks BLK1 to BLKz. The plurality of memory blocks BLK1 to BLKz are coupled to the address decoder 121 through row lines RL. The plurality of memory blocks BLK1 to BLKz are coupled to the read/write circuit 123 through bit lines BL1 to BLm. Each of the plurality of memory blocks BLK1 to BLKz includes a plurality of memory cells. In an embodiment, the plurality of memory cells may be nonvolatile memory cells. Among the plurality of memory cells, memory cells coupled to the same word line may be defined as one page. That is, the memory cell array 110 may include a plurality of pages.

Each of the memory cells of the semiconductor memory device 100 may be a Single Level Cell (SLC) for storing one data bit, a Multi Level Cell (MLC) for storing two data bits, a Triple Level Cell (TLC) for storing three data bits, or a Quad Level Cell (QLC) for storing four data bits.

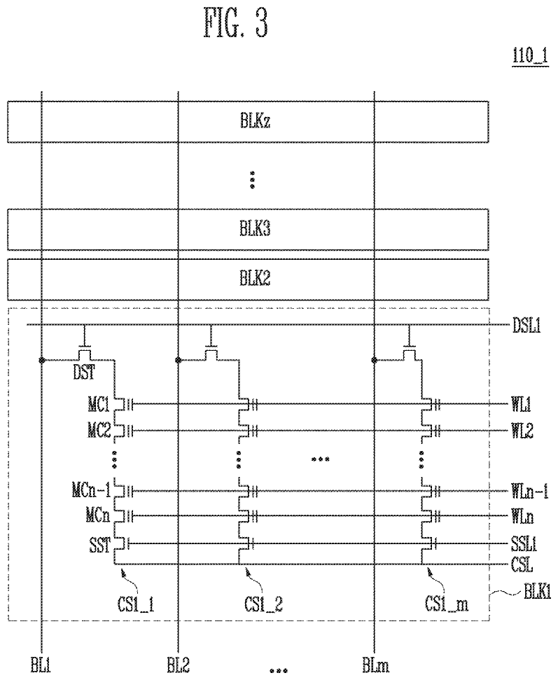

FIG. 3 is a diagram illustrating an embodiment of the memory cell array 110 of FIG. 2. A memory cell array 110_1 of FIG. 3 represents an embodiment of the memory cell array 110 of FIG. 2.

Referring to FIG. 3, first to zth memory blocks BLK1 to BLKz included in the memory cell array 110_1 are commonly coupled to first to mth bit lines BL1 to BLm. In FIG. 3, for convenience of description, components included in a first memory block BLK1 among the plurality of memory blocks BLK1 to BLKz are illustrated, and components included in each of the other memory blocks BLK2 to BLKz are omitted. It will be understood that each of the other memory blocks BLK2 to BLKz is configured identical to the first memory block BLK1.

The memory block BLK1. includes a plurality of cell strings CS1_1 to CS1_m. First to mth cell strings CS1_1 to CS1_m are coupled to the first to mth bit lines BL1 to BLm, respectively.

Each of the first to mth cell strings CS1_1 to CS1_m includes a drain select transistor DST, a plurality of memory cells MC1 to MCn coupled in series, and a source select transistor SST. The drain select transistor DST is coupled to a drain select line DSL1. First to nth memory cells MC1 to MCn are coupled to first to nth word lines WL1. to WLn, respectively. The source select transistor SST is coupled to a source select line SSL1. A drain side of the drain select transistor DST is coupled to a corresponding bit line. The drain select transistors of the first to mth cell strings CS1_1 to CS1_m are coupled to the first to mth bit lines BL1 to BLm, respectively. A source side of the source select transistor SST is coupled to a common source line CSL. In an embodiment, the common source line CSL may be commonly coupled to the first to zth memory blocks BLK1 to BLKz,

The drain select line DSL1, the first to nth word lines WL1 to WLn, and the source select line SSL1 are included in the row lines RL of FIG. 2. The drain select line DSL1, the first to nth word lines WL1 to WLn, and the source select line SSL1 are controlled by the address decoder 121. The common source line CSL is controlled by the control logic 130. The first to mth bit lines BL1 to BLm are controlled by the read/write circuit 123.

Referring back to FIG. 2, the peripheral circuit 120 may include the address decoder 121, a voltage generator 122, the read/write circuit 123, and a data input/output circuit 124.

The peripheral circuit 120 drives the memory cell array 110. For example, the peripheral circuit 120 may drive the memory cell array 110 to perform a program operation, a read operation, and an erase operation.

The address decoder 121 is coupled to the memory cell array 110 through the row lines RL. The address decoder 121 operates under the control of the control logic 130. The address decoder 121 receives an address ADDR from the control logic 130 through an input/output buffer (not shown) provided in the semiconductor memory device 100.

The address decoder 121 may decode a block address in the received address ADDR. The address decoder 121 selects at least one memory block among the memory blocks BLK1 to BLKz according to the decoded block address. The address decoder 121 may decode a row address in the received address ADDR. The address decoder 121 may select at least one word line WL of the selected memory block by applying voltages provided from the voltage generator 122 to the word line WL according to the decoded row address.

In a program operation, the address decoder 121 may apply a program voltage to the selected word line, and apply a pass voltage having a level lower than that of the program voltage to unselected word lines. In a program verify operation, the address decoder 121 may apply a verify voltage to the selected word line, and apply a verify pass voltage higher than the verify voltage to the unselected word lines.

In a read operation, the address decoder 121 may apply a read voltage to the selected word line, and apply a pass voltage higher than the read voltage to the unselected word lines.

In an embodiment, an erase operation of the semiconductor memory device 100 is performed in units of memory blocks. In an erase operation, the address ADDR input to the semiconductor memory device 100 includes a block address. The address decoder 121 may decode the block address and select one memory block according to the decoded block address. In the erase operation, the address decoder 121 may apply a ground voltage to word lines coupled to the selected memory block.

In an embodiment, the address decoder 121 may decode a column address in the address ADDR transferred thereto. The Decoded Column Address (DCA) may be transferred to the read/write circuit 123. In an example, the address decoder 121 may include components such as a row decoder, a column decoder, and an address buffer.

The voltage generator 122 may generate a plurality of voltages by using an external power voltage supplied to the semiconductor memory device 100. The voltage generator 122 operates under the control of the control logic 130.

In an embodiment, the voltage generator 122 may generate an internal power voltage by regulating the external power voltage. The internal power voltage generated by the voltage generator 122 is used as an operation voltage of the semiconductor memory device 100.

According to an embodiment of the present disclosure, the voltage generator 122 may generate a plurality of voltages by using the external power voltage or the internal power voltage. The voltage generator 122 may be configured to generate various voltages required by the semiconductor memory device 100. For example, the voltage generator 122 may generate a plurality of program voltages, a plurality of pass voltages, a plurality of select read voltages, and a plurality of unselect read voltages.

For example, the voltage generator 122 may include a plurality of pumping capacitors for receiving the internal power voltage, and generate a plurality of voltages by selectively activating the plurality of pumping capacitors under the control of the control logic 130.

The plurality of generated voltages may be supplied to the memory cell array 110 by the address decoder 121.

The read and write (read/write) circuit 123 includes first to mth page buffers PB1 to PBm. The first to mth page buffers PB1 to PBm are coupled to the memory cell array 110 through the respective first to mth bit lines BL1 to BLm. The first to mth page buffers PB1 to PBm operate under the control of the control logic 130.

The first to mth page buffers PB1 to PBm communicate data with the data input/output circuit 124. In a program operation, the first to mth page buffers PB1 to PBm receive data DATA to be stored through the data input/output circuit 124 and data lines DL.

In a program operation, when a program pulse is applied to a selected word line, the first to mth page buffers PB1 to PBm may transfer data DATA received through the data input/output circuit 124 to selected memory cells through the bit lines BL1 to BLm. Memory cells of a selected page are programmed according to the transferred data DATA. A memory cell coupled to a bit line to which a program allow voltage (e.g., a ground voltage) is applied may have an increased threshold voltage. The threshold voltage of a memory cell coupled to a bit line to which a program inhibit voltage (e.g., a power voltage) is applied may be maintained. In a program verify operation, the first to mth page buffers PB1 to PBm read page data from the selected memory cells through the bit lines BL1 to BLm.

In a read operation, the read/write circuit 123 reads data DATA from the memory cells of the selected page through the bit lines BL, and output the read data DATA to the data input/output circuit 124.

In an erase operation, the read/write circuit 123 may float the bit lines BL. In an embodiment, the read/write circuit 123 may include a column select circuit.

The data input/output circuit 124 is coupled to the first to mth page buffers PB1 to PBm through the data lines DL. The data input/output circuit 124 operates under the control of the control logic 130. In a program operation, the data input/output circuit 124 may receive data DATA to be stored from an external controller (not shown). In a read operation, the data input/output circuit 124 outputs, to the external controller, data transferred from the first to meth page buffers PB1 to PBm included in the read/write circuit 123.

The temperature sensor 150 may be embedded in the semiconductor memory device 100, to measure a temperature of the semiconductor memory device 100. Meanwhile, the temperature sensor 150 may transfer the measured result as temperature information Tmp to the control logic 130.

The control logic 130 may be coupled to the address decoder 121, the voltage generator 122, the read/write circuit 123, and the data input/output circuit 124. The control logic 130 may be configured to control overall operations of the semiconductor memory device 100. The control logic 130 may operate in response to a command CMD transferred from an external device.

The control logic 130 may further include the ready-busy signal generator 101. The ready-busy signal generator 101 may generate the ready-busy signal, based on the temperature information Tmp received from the temperature sensor 150. More specifically, when the temperature of the semiconductor memory device 100, which is measured by the temperature sensor 150, is higher than a certain reference temperature, the ready-busy signal generator 101 may maintain the busy state of the ready-busy signal for a dummy busy signal time even after a specific operation having caused the busy state is in completed. An exemplary configuration of the ready-busy signal generator 101 and an operation thereof will be described later with reference to FIGS. 7 to 12.

The interface 140 may interface data communication between the semiconductor memory device 100 and the external device. The interface 140 may include a NAND interface or NOR interface according to the kind of semiconductor memory device 100.

The interface 140 may receive the ready-busy signal from the ready-busy signal generator 101 included in the control logic 130 to output the ready-busy signal to the controller. That the ready-busy signal is disabled to a logic value “high” may mean that the semiconductor memory device 100 corresponds to the ready state, and that the ready-busy signal is enabled to a logic value “low” may mean that the semiconductor memory device 100 corresponds to the busy state. In another embodiment, that an output end of the ready-busy signal has high impedance may mean that the semiconductor memory device 100 corresponds to the ready state, and that the output end of the ready-busy signal has low impedance may mean that the semiconductor memory device 100 corresponds to the busy state. Although FIG. 2 illustrates that the ready-busy signal generator 101 is included in the control logic 130, in some embodiments, the semiconductor memory device 100 may include a ready-busy signal generator 101 located separately from the semiconductor memory device 100.

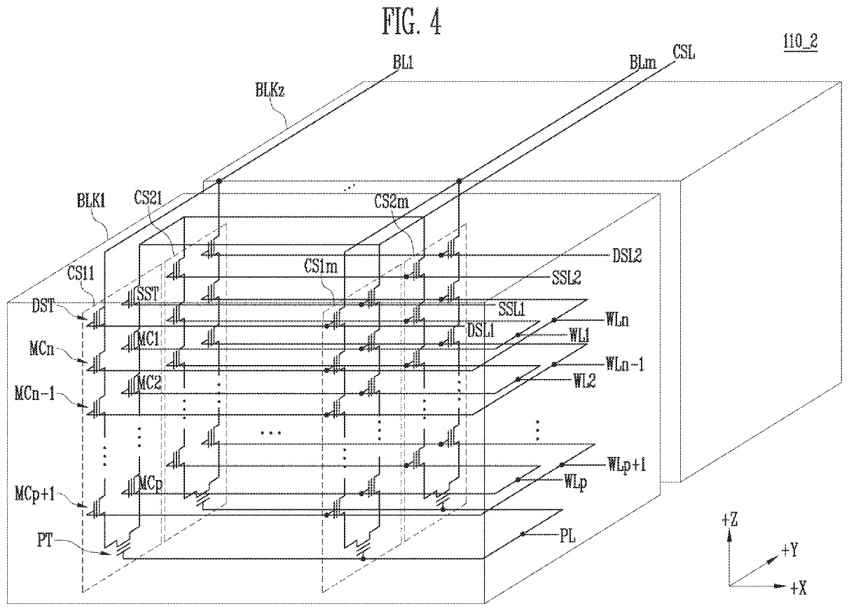

FIG. 4 is a diagram illustrating an embodiment of the memory cell array 110 of FIG. 2.

Referring to FIG. 4, a memory cell array 110_2 includes a plurality of memory blocks BLK1 to BLKz. In FIG. 4, for convenience of description, an internal configuration of a first memory block BLK1 is illustrated, and internal configurations of the other memory blocks BLK2 to BLKz are omitted, It will be understood that second to zth memory blocks BLK2 to BLKz are also configured identical to the first memory block BLK1.

The first memory block BLK1 includes a plurality of cell strings CS11 to CS1m and CS21 to CS2m. In an embodiment, each of the plurality of cell strings CS11 to CS1m and CS21 to CS2m may be formed in a ‘U’ shape. In the first memory block BLK1, m cell strings are arranged in a row direction (i.e., a +X direction). FIG. 4 illustrates that two cell strings are arranged in a column direction (i.e., a +Y direction). However, this is for convenience of description, and it will be understood that three or more cell strings may be arranged in the column direction.

Each of the plurality of cell strings CS11 to CS1m and CS21. to CS2m includes at least one source select transistor SST, first to nth memory cells MC1 to MCn, a pipe transistor PT, and at least one drain select transistor DST.

The select transistors SST and DST and the memory cells MC1 to MCn may have structures similar to one another. In an embodiment, each of the select transistors SST and DST and the memory cells MC1 to MCn may include a channel layer, a tunneling insulating layer, a charge storage layer, and a blocking insulating layer. In an embodiment, a pillar for providing the channel layer may be provided in each cell string. In an embodiment, a pillar for providing at least one of the channel layer, the tunneling insulating layer, the charge storage layer, and the blocking insulating layer may be provided in each cell string.

The source select transistor SST of each cell string is coupled between a common source line CSL and memory cells MC1 to MCp.

In an embodiment, the source select transistors of cell strings arranged on the same row are coupled to a source select line extending in the row direction, and the source select transistors of cell strings arranged on different rows are coupled to different source select lines. In FIG. 4, the source select transistors of the cell strings CS11 to CS1m on a first row are coupled to a first source select line SSL1. The source select transistors of the cell strings CS21 to CS2m on a second row are coupled to a second source select line SSL2.

In another embodiment, the source select transistors of the cell strings CS11 to CS1m and CS21 to CS2m may be commonly coupled to one source select line.

The first to nth memory cells MC1 to MCn of each cell string are coupled between the source select transistor SST and the drain select transistor DST.

The first to nth memory cells MC1 to MCn may be divided into first to pth memory cells MC1 to MCp and a (p+i)th to nth memory cells MCp+1 to MCn. The first to pth memory cells MC1 to MCp are sequentially arranged in the opposite direction of a +Z direction, and are coupled in series between the source select transistor SST and the pipe transistor PT. The (p+1)th to nth memory cells MCp+1 to MCn are sequentially arranged in the +Z direction, and are coupled in series between the pipe transistor PT and the drain select transistor DST. The first to pth memory cells MC1 to MCp and the (p+1)th to nth memory cells MCp+1 to MCn are coupled through the pipe transistor PT. Gate electrodes of the first to nth memory cells MC1 to MCn of each cell string are coupled to first to nth word lines WL1 to WLn, respectively.

In an embodiment, at least one of the first to nth memory cells MC1 to MCn may be used as a dummy memory cell. When the dummy memory cell is provided, the voltage or current of a corresponding cell string is stably controlled. Accordingly, the reliability of data stored in the memory block BLK1 can be improved.

A gate of the pipe transistor PT of each cell string is coupled to a pipe line PL.

The drain select transistor DST of each cell string is coupled between a corresponding bit line and the memory cells MCp+1 to MCn. Cell strings arranged in the row direction are coupled to a drain select line extending in the row direction. The drain select transistors of the cell strings CS11 to CS1m on the first row are coupled to a first drain select line DSL1. The drain select transistors of the cell strings CS21 to CS2m on the second row are coupled to a second drain select line DSL2.

Cell strings arranged in the column direction are coupled to a bit line extending in the column direction. In FIG. 4, the cell strings CS11 and CS21 on a first column are coupled to a first bit line BL1. The cell strings CS1m and CS2m on an mth column are coupled to an mth bit line BLm.

Memory cells coupled to the same word line in the cell strings arranged in the row direction constitute one page. For example, memory cells coupled to the first word line WL1 in the cell strings CS11 to CS1m on the first row constitute one page. Memory cells coupled to the first word line WL1 in the cell strings CS21 to CS2m on the second row constitute another page. When any one of the drain select lines DSL1. and DSL2 is selected, cell strings arranged in one row direction may be selected. When any one of the word lines WL1 to WLn is selected, one page may be selected in the selected cell strings.

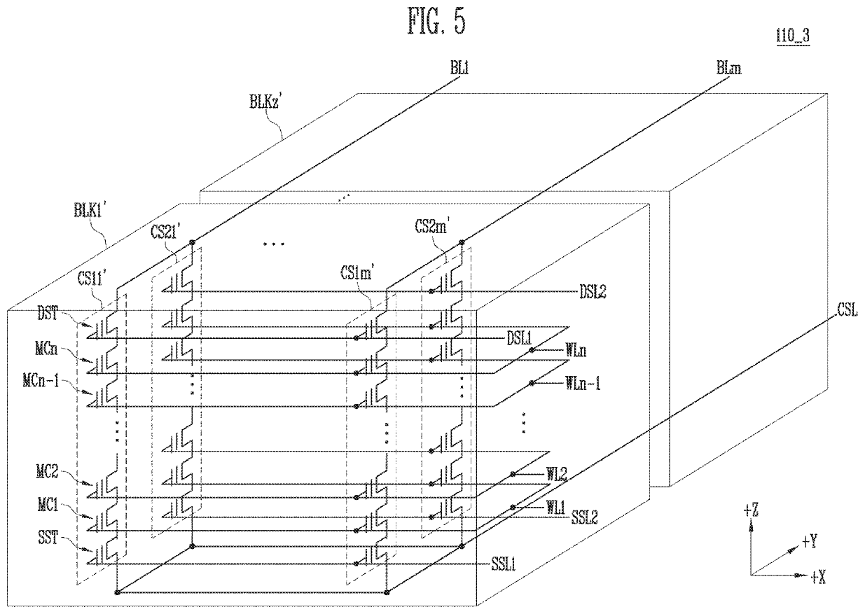

FIG. 5 is a diagram illustrating an embodiment of the memory cell array 100 of FIG. 2.

Referring to FIG. 5, a memory cell array 110_3 includes a plurality of memory blocks BLK1′ to BLKz′. In FIG. 5, for convenience of description, an internal configuration of a first memory block BLK1′ is illustrated, and internal configurations of the other memory blocks BLK2′ to BLKz′ are omitted. It will be understood that second to zth memory blocks BLK2′ to BLKz′ are also configured identical to the first memory block BLK1′.

The first memory block BLK1′ includes a plurality of cell strings CS11′ to CS1m′ and CS21′ to CS2m′. Each of the plurality of cell strings CS11′ to CS1m′ and CS21′ to CS2m′ extends along the +Z direction. In the first memory block BLK1′, m cell strings are arranged in the +X direction. FIG. 5 illustrates that two cell strings are arranged in the +Y direction. However, this is for convenience of description, and it will be understood that three or more cell strings may be arranged in the column direction.

Each of the plurality of cell strings CS11′ to CS1m′ and CS21′ to CS2m′ includes at least one source select transistor SST, first to nth memory cells MC1 to MCn, and at least one drain select transistor DST.

The source select transistor SST of each cell string is coupled between a common source line CSL and the memory cells MC1 to MCn. The source select transistors of cell strings arranged on the same row are coupled to the same source select line. The source select transistors of the cell strings CS11′ to CS1m′ arranged on a first row are coupled to a first source select line SSL1. Source select transistors of the cell strings

CS21′ to CS2m′ arranged on a second row are coupled to a second source select line Sa2. In another embodiment, the source select transistors of the cell strings CS11′ to CS1m′ and CS21′ to CS2m′ may be commonly coupled to one source select line.

The first to nth memory cells MC1 to MCn of each cell string are coupled in series between the source select transistor SST and the drain select transistor DST. Gate electrodes of the first to nth memory cells MC1 to MCn are coupled to first to nth word lines WL1 to WLn, respectively.

In an embodiment, at least one of the first to nth memory cells MC1 to MCn may be used as a dummy memory cell. When the dummy memory cell is provided, the voltage or current of a corresponding cell string is stably controlled. Accordingly, the reliability of data stored in the memory block BLK1′ can be improved.

The drain select transistor DST of each cell string is coupled between a corresponding bit line and the memory cells MC1 to MCn. The drain select transistors of cell strings arranged in the row direction are coupled to a drain select line extending in the row direction. The drain select transistors of the cell strings CS11′ to CS1m′ on the first row are coupled to a first drain select line DSL1. The drain select transistors of the cell strings CS21′ to CS2m′ on the second row are coupled to a second drain select line DSL2.

As a result, the memory block BLK1′ of FIG. 5 has a circuit similar to that of the memory block BLK1 of FIG. 4, except that the pipe transistor PT is excluded from each cell string.

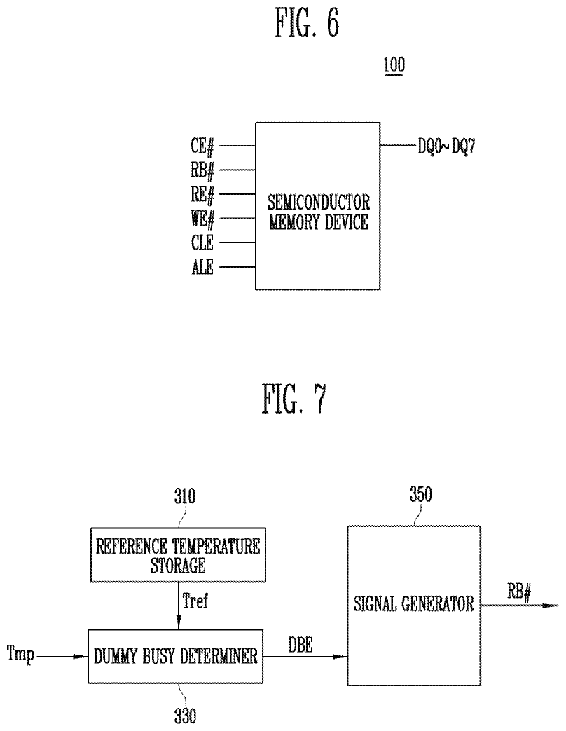

FIG. 6 is a diagram illustrating a pin configuration of the semiconductor memory device.

Referring to FIG. 6, the semiconductor memory device 100 communicates with an external controller (not shown) through a plurality of lies.

The semiconductor memory device 100 communicates with the controller through a chip enable line CE#, a command latch enable line CLE, an address latch enable line ALE, a write enable line WE#, a read enable line RE#, a ready-busy line RB#, and data input/output lines DQ0 to DQ7.

The chip enable line CE# represents a signal indicating that the semiconductor memory device 100 is operable. The signal of the chip enable line CE# may be selectively applied to storage devices coupled to the same channel. The signal of the chip enable line CE# represents that all operations in a corresponding chip are possible while the signal of the chip enable line CE# is falling to low. When the signal of the chip enable line CE# becomes high, the corresponding chip may be in a standby state.

A signal of the ready-busy line RB# falls to low while an operation is being performed in the chip, to allow the chip not to exchange any signal with the outside. When the signal of the ready-busy line RB# becomes high, the signal of the ready-busy line RB# represents that the chip is in a ready state.

A signal of the command latch enable line CLE becomes high while a command CMD is being input to a selected storage device. A signal of the address latch enable line ALE becomes high while an address ADD is being input to the storage device.

The command CMD and the address ADD is input to the storage device when the level of a signal of the write enable signal WE# is changed from high to low.

The signal of the write enable signal WE# is toggled when the command and the address are loaded into the storage device, and a signal of the read enable signal RE# is toggled when data is loaded into the controller.

The data input/output lines DQ0 to DQ7 input a command, an address, and data to the semiconductor memory device 100, or output data to the controller. Since the data is configured with 8 bits, the number of data input/output lines DQ0 to DQ7 is also 8. However, the number of data input/output lines is not limited to 8. In various embodiments, the number of data input/output lines may be extended to 16 or 32.

According to an embodiment of the present disclosure, a ready-busy signal output to the ready-busy line RB# is controlled, regardless of the actual state of the semiconductor memory device 100, such that a time at which the state of the ready-busy signal is changed from the busy state to the ready state according to the temperature of the semiconductor memory device 100. Accordingly, when the temperature of the semiconductor memory device 100 increases, throttling can be performed without control of the controller 200.

In general, when the temperature of a conventional semiconductor memory device increases, a throttling operation is performed under the control of the controller. For example, the controller may receive temperature information of the semiconductor memory device. When the temperature of the semiconductor memory device increases to a specific reference value or more, the controller may delay or postpone a command transferred to the semiconductor memory device for a certain time. Accordingly, the temperature of the semiconductor memory device is prevented from being excessively increased by a continuous operation. This is referred to as a “throttling operation.”

However, when the controller controls and manages the throttling operation performing according to an increase in temperature, the level of difficulty of configuration of the controller may increase. In particular, in a memory system including a plurality of semiconductor memory devices, i.e., a plurality of memory chips, cost required to allow the controller to control and manage the throttling operation performing according to an increase in temperature may increase.

According to the semiconductor memory device 100 and the operating method thereof according to the present disclosure, when the temperature of the semiconductor memory device 100 increases, a busy time is intentionally set for a long duration, Accordingly, the throttling operation according to an increase in temperature of the semiconductor memory device 100 can be performed without control of the controller 200. In particular, in a memory system 1000 including a plurality of semiconductor memory devices 100, each semiconductor memory device 100 can individually perform the throttling operation according to an increase in temperature. Accordingly, the reliability of an operation according to a temperature of the memory system can be improved without any separate throttling operation performed by the controller 200.

FIG. 7 is a block diagram illustrating an exemplary embodiment of the ready-busy signal generator 101 of FIG. 2.

Referring to FIG. 7, the ready-busy signal generator 101 may include a reference temperature storage 310, a dummy busy determiner 330, and a signal generator 350.

The reference temperature storage 310 may store a reference temperature Tref for determining whether a dummy busy time is to be applied. The reference temperature Tref may be variously determined, if necessary. In an example, the reference temperature storage 310 may be configured as a register. In another example, the reference temperature storage 310 may be configured as a Read Only Memory (ROM).

The dummy busy determiner 330 may receive temperature information Tmp from the temperature sensor 150 shown in FIG. 2. Also, the dummy busy determiner 330 may receive the reference temperature Tref from the reference temperature storage 310. The dummy busy determiner 330 may generate a dummy busy activation signal DBE by comparing values indicated by the temperature information Tmp and the reference temperature Tref The dummy busy activation signal DBE may have different values according to the result obtained by comparing the values indicated by the temperature information Tmp and the reference temperature Tref.

In an example, when the value indicated by the temperature information Tmp is higher than the value indicated by the reference temperature Tref, the dummy busy activation signal DBE may be enabled to a “low” state. When the value indicated by the temperature information Tmp is equal to or lower than the value indicated by the reference temperature Tref, the dummy busy activation signal DBE may be disabled to a “high” state.

In another example, when the value indicated by the temperature information Tmp is higher than the reference temperature Tref, the dummy busy activation signal DBE may be enabled to the “high” state. When the value indicated by the temperature information Tmp is equal to or lower than the reference temperature Tref, the dummy busy activation signal DBE may be disabled to the “low” state.

The signal generator 350 may generate a ready-busy signal RB#, based on the dummy busy activation signal DBE.

When the dummy busy activation signal DBE is enabled, this means that a temperature measured by the temperature sensor 150 is higher than the reference temperature Tref. Therefore, the signal generator 350 may keep providing a ready-busy signal representing the busy state for the dummy busy time. That is, even after an internal operation of the semiconductor memory device 1000 is completed, the state of the ready-busy signal may be maintained as the busy state during the dummy busy time. When the dummy busy time elapses, the state of the ready-busy signal is changed to the ready state.

When the dummy busy activation signal DBE is disabled, this means that a temperature measured by the temperature sensor 150 is equal to or lower than the reference temperature Tref. Therefore, the signal generator 350 may generate a ready-busy signal representing the ready state. That is, after an internal operation of the semiconductor memory device 100 is completed, the state of the ready-busy signal may be changed from the busy state to the ready state.

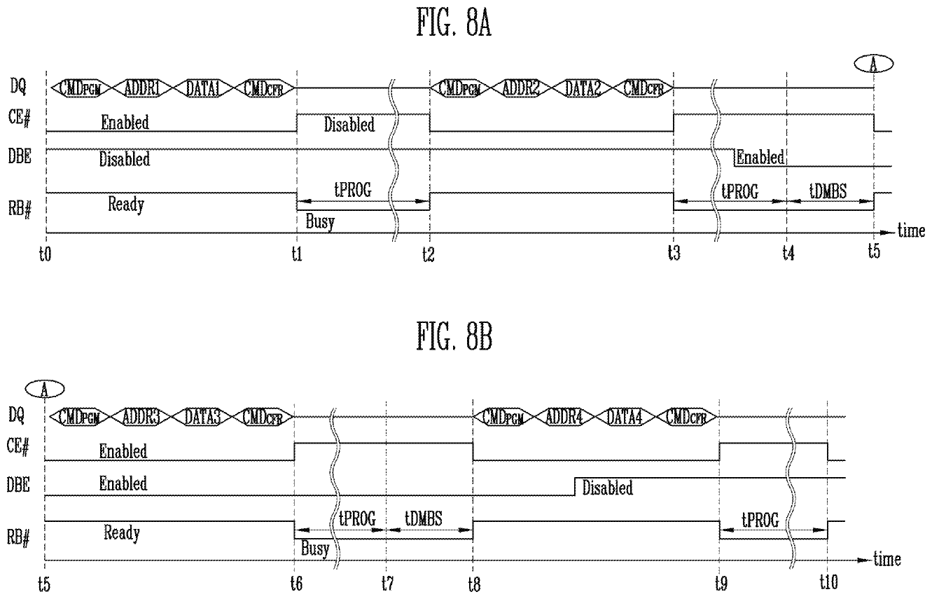

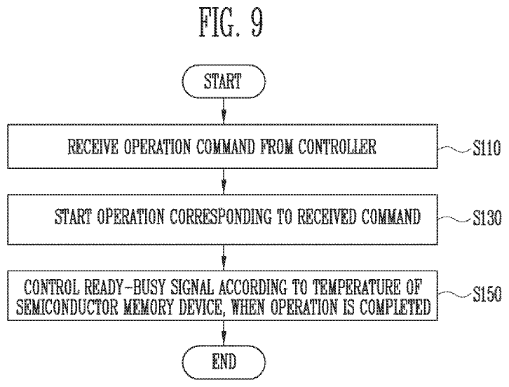

FIGS. 8A and 8B are timing diagrams illustrating an operation of the semiconductor memory device according to an embodiment of the present disclosure. In FIGS. 8A and 8B, essential signals for describing features of the present disclosure are illustrated, and the other signals are omitted for convenience of illustration.

Referring to FIGS. 8A and 8B, a program operation of the semiconductor memory device according to an embodiment of the present disclosure is illustrated. In particular, a signal of a data input/output line

DQ, a signal of a chip enable line CE#, a dummy busy activation signal DBE, and a ready-busy signal RB# are illustrated. The data input/output line DQ of FIGS. 8A and 8B is a simplified representation of the data input/output lines DQ0 to DQ7 shown in FIG. 6.

At a time t0, the controller 200 may sequentially transfer a program start command CMD_{PGM}, a first address ADDR1, first data DATA1, and a confirm command CMD_{CFR} to the semiconductor memory device 100 through the data input/output line DQ. When the program start command CMD_{PGM} is transferred to the semiconductor memory device 100, the semiconductor memory device 100 prepares to receive a program address and data. Subsequently, the first address ADDR1 and the first data DATA1 are transferred to the semiconductor memory device 100. The first address ADDR1 may be transferred to the control logic 130. The first data DATA1 may be stored in the first to mth page buffers PB1 to PBm of the read/write circuit 123.

During a period t0 to t1, the chip enable line CE# is enabled (i.e., activated), and the ready-busy signal RB# maintains the ready state. Meanwhile, the dummy busy activation signal DBE is disabled (i.e., inactivated) to the “high” state.

When the confirm command CMD_{CFR} is transferred to the semiconductor memory device 100, an internal program operation of the semiconductor memory device 100 is started from a time t1. When the internal program operation of the semiconductor memory device 100 is started, the chip enable line CE# is disabled, and the state of the ready-busy signal RB# is changed to the busy state. The internal program operation of the semiconductor memory device 100 is performed for a program time tPROG. At a time t2, the internal program operation is completed. Meanwhile, since the dummy busy activation signal DBE maintains the “high state,” i.e., an inactivation state at the time t2, the signal generator 350 of FIG. 7 changes the state of the ready-busy signal RB# from the busy state to the ready state without applying a dummy busy time. Accordingly, a first program operation is completed at the time t2.

Meanwhile, when the program operation is completed, a second program operation may be started from the time t2. At the time t2, the controller 200 may sequentially transfer a program start command CMD_{PCM}, a second address ADDR2, second data DATA2, and a confirm command CMD_{CFR} to the semiconductor memory device 100 through the data input/output line DQ. When the program start command CMD_{PGM} is transferred to the semiconductor memory device 100, the semiconductor memory device 100 prepares to receive a program address and data. Subsequently, the second address ADDR2 and the second data DATA2 are transferred to the semiconductor memory device 100. The second address ADDR2 may be transferred to the control logic 130. The second data DATA2 may be stored in the first to mth page buffers PB1 to PBm of the read/write circuit 123.

During a period t2 to t3, the chip enable line CE# is enabled, and the ready-busy signal RB# maintains the ready state. Meanwhile, the dummy busy activation signal DBE maintains the “high state.”

When the confirm command CMD_{CFR} is transferred to the semiconductor memory device 100, an internal program operation of the semiconductor memory device 100 is started from a time t3. When the internal program operation of the semiconductor memory device 100 is started, the chip enable line CE# is disabled, and the state of the ready-busy signal RB# is changed to the busy state. The internal program operation of the semiconductor memory device 100 is performed for a program time tPROG. At a time t4, the internal program operation is completed.

Meanwhile, while the internal program operation is being performed (that is, during the time tPROG), the temperature of the semiconductor memory device 100 increases, and the state of the dummy busy activation signal DBE may be changed to the “low state,” i.e., an enabled state. Since the dummy busy activation signal DBE is in the enabled state at the time t4 that is a time at which the internal program has been completed, the signal generator 350 may generate the ready-busy signal RB# by applying a dummy busy time tDMBS. Accordingly, the busy state of the ready-busy signal RB# is maintained for the dummy busy time tDMBS from the time t4. Subsequently, the state of the ready-busy signal RB# is changed to the ready state at a time t5 at which the dummy busy time tDMBS is expired.

Referring to FIG. 8B, an operation from the time t5 (A) of FIG. 8A is illustrated. At the time t5, a third program operation is performed. Accordingly, the semiconductor memory device 100 receives a program start command CMD_{PGM}, a third address ADDR3, third data DATA3, and a confirm command CMD_{CFR}.

When the semiconductor memory device 100 maintains a high temperature, the dummy busy activation signal DBE may maintain the enabled state. Therefore, after an internal program operation is performed during a program time tPROG from a time t6, the busy state of the ready-busy signal RB# may be maintained during a dummy busy time tDMBS from a time t7. Subsequently, the state of the ready-busy signal RB# is changed to the ready state at a time t8 at which the dummy busy time tDMBS is expired.

Subsequently, at a time t8, a fourth program operation is performed. Accordingly, the semiconductor memory device 100 receives a program start command CMD_{PGM}, a fourth address ADDR4, fourth data DATA4, and a confirm command CMD_{CFR}.

When a dummy busy time is applied, the temperature of the semiconductor memory device 100 may be lower than the reference temperature. Therefore, during a time between the time t8 and t9 when the temperature of the semiconductor memory device 100 becomes lower than the reference temperature, the state of the dummy busy activation signal DBE may be changed to the disabled state.

When the fourth program operation of the semiconductor memory device 100 is started at time t9, the chip enable line CE# is disabled, and the state of the ready-busy signal RB# is changed to the busy state. After an internal program operation is performed during a program time tPROG from a time t9, at a time t10, the state of the ready-busy signal RB# may be changed from the busy state to the ready state.

As described above, according to the semiconductor memory device and the operating method thereof according to the present disclosure, the dummy busy time is selectively applied according to the temperature of the semiconductor memory device. Accordingly, the throttling operation according to an increase in temperature of the semiconductor memory device can be performed without control of the controller.

Although the program operation is exemplarily described in FIGS. 8A and 8B, the semiconductor memory device and the operating method thereof according to the present disclosure are not limited thereto. For example, it will be apparent that, in an erase operation or read operation, the dummy busy time may be selectively applied in the above-described manner according to the temperature of the semiconductor memory device.

FIG. 9 is a flowchart illustrating an operating method of the semiconductor memory device according to another embodiment of the present disclosure.

Referring to FIG. 9, the semiconductor memory device 100 receives an operation command from the controller at step S110, starts an operation corresponding to the received command at step S130, and controls a ready-busy signal according to a temperature of the semiconductor memory device 100 when the operation is completed at step S150.

In the step S110, the received operation command may be a program command. In another example, the operation command may be a read command or erase command.

In the step S130, an internal operation corresponding to the received command is started. Referring to the example of FIGS. 8A and 8B, the internal program operation may be started in the step S130.

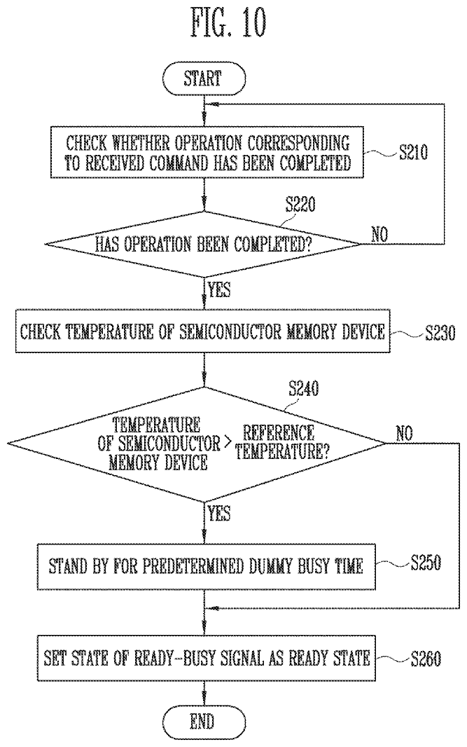

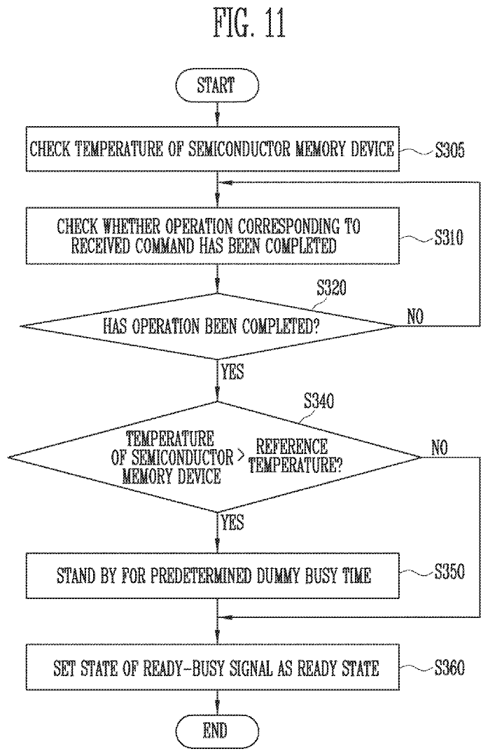

Subsequently, in the step S150, the ready-busy signal may be controlled based on the dummy busy activation signal DBE. An exemplary embodiment of the step S150 will be described in more detail later with reference to FIGS. 10 and 11.

FIG. 10 is a flowchart illustrating an embodiment of the step S150 of FIG. 9.

Referring to FIG. 10, the step S150 of FIG. 9, in which the semiconductor device 100 controls the ready-busy signal according to the temperature of the semiconductor memory device 100, may start by checking whether the operation corresponding to the received command has been completed at step S210. When the operation is not completed as the result obtained by determining whether the operation has been completed in step S220 (that is, “NO” at step S220), the operating method proceeds back to the step S210.

When the operation is completed as the result obtained by determining whether the operation has been completed in step S220 (that is, “YES”), a temperature of the semiconductor memory device 100 is checked in step S230. in an embodiment, in the step S230, the temperature sensor 150 shown in FIG. 2 may measure a temperature of the semiconductor memory device 100 and transfer the measured temperature as temperature information Tmp to the dummy busy determiner 330. The dummy busy determiner 330 may check the received temperature information Tmp.

In another embodiment, the temperature sensor 150 may measure a temperature of the semiconductor memory device 100 at an arbitrary time before the step S230 and transfer the measured temperature as temperature information Tmp to the dummy busy determiner 330. The dummy busy determiner 330 may store the received temperature information Tmp. For example, the temperature sensor 150 may periodically transfer the temperature information Tmp according to a predetermined period. The dummy busy determiner 330 may include a storage means, e.g., a register for storing the received temperature information Tmp. Subsequently, in the step S230, the dummy busy determiner 330 may check the stored temperature information Tmp.

Subsequently in step S240, the temperature of the semiconductor memory device 100 is compared with a reference temperature. When the temperature of the semiconductor memory device 100 is higher than the reference temperature as the comparison result (that is, “YES” at step S240), the semiconductor memory device 100 stands by for a predetermined dummy busy time in step S250. The step S250 may be performed by maintaining the state of the ready-busy signal as the busy state for a dummy busy time tDMBS. When the dummy busy time tDMBS elapses, the state of the ready-busy signal is set as the ready state in step S260.

Meanwhile, when the temperature of the semiconductor memory device 100 is equal to or lower than the reference temperature as the result obtained by comparing the temperature of the semiconductor memory device 100 with the reference temperature (that is, “NO” at step S240), the state of the ready-busy signal is changed from the busy state to the ready state in step S260.

FIG. 11 is a flowchart illustrating an embodiment of the step S150 of FIG. 9.

Referring to FIG. 11, the step S150 of FIG. 9, in which the semiconductor memory device 100 controls the ready-busy signal according to the temperature of the semiconductor memory device 100, may start by checking a temperature of the semiconductor memory device 100 at step S305. In an embodiment, in the step S305, the temperature sensor 150 may measure a temperature of the semiconductor memory device 100 and transfer the measured temperature as temperature information Tmp to the dummy busy determiner 330. The dummy busy determiner 330 may check the received temperature information Tmp. In another embodiment, the temperature sensor 150 may measure a temperature of the semiconductor memory device 100 at an arbitrary time before the step S305 and transfer the measured temperature as temperature information Tmp to the dummy busy determiner 330. The dummy busy determiner 330 may store the received temperature information Tmp. For example, the temperature sensor 150 may periodically transfer the temperature information Tmp to the dummy busy determiner 330 according to a predetermined period. Subsequently, in the step S305, the dummy busy determiner 330 may check the stored temperature information Tmp.

Subsequently, whether the operation corresponding to the received command has been completed is checked in step S310. When the operation is not completed as the result obtained by determining whether the operation has been completed in step S320 (that is, “No” at step S320), the operating method proceeds back to the step S310.

When the operation is completed as the result obtained by determining whether the operation has been completed in step S320 (that is, “YES” at step S320), the temperature of the semiconductor memory device 100 is compared with a reference temperature in step S340. When the temperature of the semiconductor memory device 100 is higher than the reference temperature as the comparison result (that is, “YES” at step S340), the semiconductor memory device 100 stands by for a predetermined dummy busy time in step S350. The step S350 may be performed by maintaining the state of the ready-busy signal as the busy state for a dummy busy time tDMBS. When the dummy busy time tDMBS elapses, the state of the ready-busy signal is set as the ready state in step S360.

Meanwhile, when the temperature of the semiconductor memory device 100 is equal to or lower than the reference temperature as the result obtained by comparing the temperature of the semiconductor memory device with the reference temperature (that is, “NO” at step S340), the state of the ready-busy signal is changed from the busy state to the ready state in step S360.

In the embodiment of FIG. 10, whether the operation corresponding to the received command has been completed is first checked in step S210, and the temperature of the semiconductor memory device 100 is then subsequently checked in step S230. On the other hand, in the embodiment of FIG. 11, the temperature of the semiconductor memory device 100 is first checked in step S305, and whether the operation corresponding to the received command has been completed is then subsequently checked in step S310. As illustrated in the embodiments of FIGS. 10 and 11, the time at which the temperature of the semiconductor memory device 100 is checked may be variously determined.

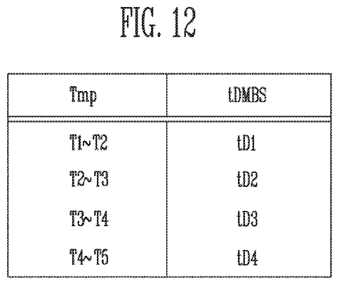

FIG. 12 is a diagram illustrating an exemplary embodiment of a dummy busy table.

Referring to FIG. 12, the dummy busy table, which may be stored in the reference temperature storage 310, includes dummy busy times tD1, tD2, tD3, and tD4 corresponding to a plurality of temperature ranges T1 to T2, T2 to T3, T3 to T4, and T4 to T5. In the semiconductor memory device 100 according to the embodiment of the present disclosure, the plurality of dummy busy times tD1, tD2, tD3, and tD4 may be applied according to a value of temperature information Tmp received from the temperature sensor 150. To this end, the reference temperature storage 310 may store a plurality of reference temperatures. For example, the reference temperature storage 310 may store temperatures T1, T2, T3, T4, and T5 for comparison with reference temperatures Tref.

The dummy busy determiner 330 may determine a dummy busy time to be applied among the dummy busy times tD1, tD2, tD3, and tD4 by comparing the values indicated by the temperature information Tmp received from the temperature sensor 150 and the temperatures T1, T2, T3, T4, and T5 provided as the reference temperatures Tref. In an embodiment, when the value indicated by the temperature information increases, the dummy busy time may be determined to have a long duration. For example, when the temperature T2 is higher than the temperature T1, the temperature T3 is higher than the temperature T2, the temperature T4 is higher than the temperature T3, and the temperature T5 is higher than the temperature T4, the dummy busy time tD2 may be longer than the dummy busy time tD1, the dummy busy time tD3 may be longer than the dummy busy time tD2, the dummy busy time tD4 may be longer than the dummy busy time tD3, and the dummy busy time tD5 may be longer than the dummy busy time tD4.

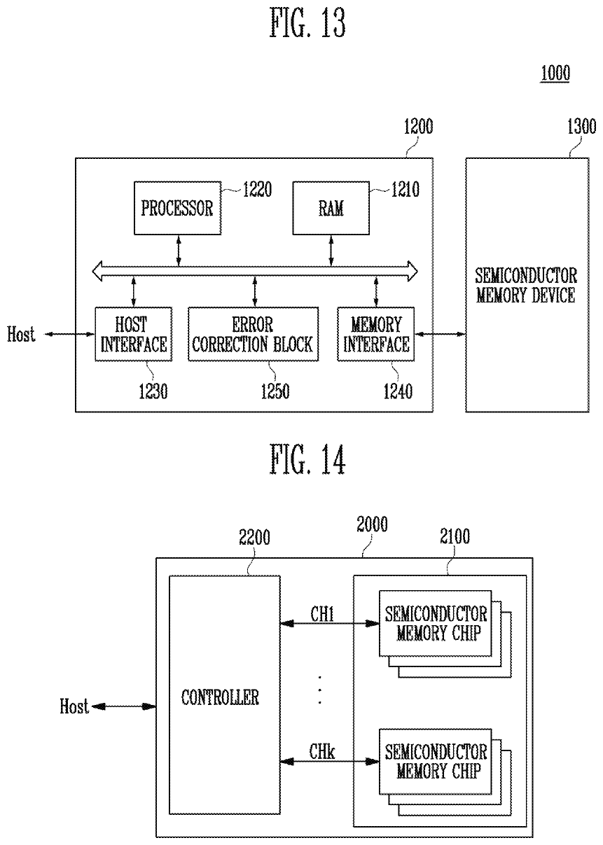

FIG. 13 is a block diagram illustrating a memory system 1000 including the semiconductor memory device of FIG. 2.

Referring to FIG. 13, the memory system 1000 includes a semiconductor memory device 1300 and a controller 1200.

The semiconductor memory device 1300 may be configured and operated identically to the semiconductor memory device 100 described with reference to FIG. 2. Hereinafter, overlapping descriptions will be omitted.

The controller 1200 is coupled to a host Host and the semiconductor memory device 1300. The controller 1200 is configured to access the semiconductor memory device 1300 in response to a request from the host Host. For example, the controller 1200 is configured to control read, program, erase, and background operations of the semiconductor memory device 1300. The controller 1200 is configured to provide an interface between the semiconductor memory device 1300 and the host Host. The controller 1200 is configured to drive firmware for controlling the semiconductor memory device 1300.

The controller 1200 includes a random access memory (RAM) 1210, a processor 1220, a host interface 1230, a memory interface 1240, and an error correction block 1250.

The RAM 1210 is used as any one of a working memory of the processor 1220, a cache memory between the semiconductor memory device 1300 and the host Host, and a buffer memory between the semiconductor memory device 1300 and the host Host.

The processor 1220 controls overall operations of the controller 1200. The processor 1220 controls a read, program, erase, and background operations of the semiconductor memory device 1300. The processor 1220 drives firmware for controlling the semiconductor memory device 1300. The processor 1220 may perform a function of a flash translation layer (FTL). The processor 1220 may translate a logical block address (LBA) provided by the host Host through the FTL into a physical block address (PBA). The FTL may receive an LBA, using a mapping table, to he translated into a PBA. Several address mapping methods of the FTL exist according to mapping units. A representative address mapping method includes a page mapping method, a block mapping method, and a hybrid mapping method.

The processor 1010 is configured to randomize data received from the host Host. For example, the processor 1010 may randomize data received from the host Host, using a randomizing seed. The randomized data is provided as data to be stored to the memory device to be programmed in the memory cell array.

In a read operation, the processor 1220 is configured to derandomize data received from the memory device. For example, the processor 1220 may derandomize data received from the memory device, using a derandomizing seed. The derandomized data may be output to the host Host.

In an embodiment, the processor 1220 may perform randomizing and derandomizing by driving software or firmware.

The host interface 1230 includes a protocol for exchanging to data between the host Host and the controller 1200. In an exemplary embodiment, the controller 1200 is configured to communicate with the host Host through at least one of various interface protocols such as a Universal Serial Bus (USB) protocol, a Multi-Media Card (MMC) protocol, a Peripheral Component Interconnection (PCI) protocol, a PCI-Express (PCI-E) protocol, an Advanced Technology Attachment (ATA) protocol, a Serial-ATA protocol, a Parallel-ATA protocol, a Small Computer Small Interface (SCSI) protocol, an Enhanced Small Disk Interface (ESDI) protocol, an Integrated Drive Electronics (IDE) protocol, and a private protocol.

The memory interface 1240 interfaces with the semiconductor memory device 1300. For example, the memory interface 1240 may include a NAND interface or a NOR interface.

The error correction block 1250 is configured to detect and correct an error of data received from the semiconductor memory device 1300 by using an error correction code (ECC). The error correction block 1250 may correct an error of read page data, using an ECC. The error correction block 1250 may correct an error, using coded modulation including low density parity check (LDDC) code, Bose, Chaudhuri, and Hocquenghem (BCH) code, turbo code, Reed-Solomon code, convolution code, recursive systematic code (RSC), trellis-coded modulation (TCM), block coded modulation (BCM), Hamming code, etc.

In a read operation, the error correction block 1250 may correct an error of read page data. When error bits of which number exceeds an error correctable bit number are included in the read page data, decoding may fail. When error bits of which number is equal to or smaller than the error correctable bit number are included in the read page data, the decoding may succeed. The success of the decoding represents that a corresponding read command has passed. The failure of the decoding represents that the corresponding command has failed. When the decoding succeeds, the controller 1200 outputs the page data of which error has been corrected to the host Host.

The controller 1200 and the semiconductor memory device 1300 may be integrated into one semiconductor device. In an exemplary embodiment, the controller 1200 and the semiconductor memory device 1300 may be integrated into one semiconductor device, to constitute a memory card. For example, the controller 1200 and the semiconductor memory device 1300 may be integrated into one semiconductor device, to constitute a memory card such as a PC card (Personal Computer Memory Card International Association (PCMCIA)), a Compact Flash (CF) card, a Smart Media Card (SM or SMC), a memory stick, a Mufti-Media Card (MMC, RS-MMC or MMCmicro), an SD Card (SD, miniSD, microSD or SDHC), or a Universal Flash Storage (UFS).

The controller 1200 and the semiconductor memory device 1300 may be integrated into one semiconductor device to constitute a semiconductor drive (solid state drive (SSD)). The semiconductor drive SSD includes a storage device configured to store data in a semiconductor memory. If the memory system 1000 is used as the semiconductor drive SSD, the operating speed of the host Host coupled to the memory system 1000 can be remarkably improved.

As another example, the memory system 1000 may be provided as one of various components of an electronic device such as a computer, an Ultra Mobile PC (UMPC), a workstation, a net-book, a Personal Digital Assistant (PDA), a portable computer, a web tablet, a wireless phone, a mobile phone, a smart phone, an e-book, a Portable Multimedia Player (PMP), a portable game console, a navigation system, a black box, a digital camera, a 3-dimensional television, a digital audio recorder, a digital audio player, a digital picture recorder, a digital picture player, a digital video recorder, a digital video player, a device capable of transmitting/receiving information in a wireless environment, one of various electronic devices that constitute a home network, one of various electronic devices that constitute a computer network, one of various electronic devices that constitute a telematics network, an RFID device, or one of various components that constitute a computing system.

In an exemplary embodiment, the semiconductor memory device 1300 or the memory system 1000 may be packaged in various forms. For example, the semiconductor memory device 100 or the memory system 1000 may be packaged in a manner such as Package On Package (PoP), Ball Grid Arrays (BGAs), Chip Scale Packages (CSPs), Plastic Leaded Chip Carrier (PLCC), Plastic Dual In-line Package (PDIP), die in Waffle pack, die in wafer form, Chip On Board (COB), CERamic Dual In-line Package (CERDIP), plastic Metric Quad Flat Pack (MQFP), Thin Quad Flat Pack (TQFP), Small Outline Integrated Circuit (SOIC), Shrink Small Outline Package (SSOP), Thin Small Outline Package (TSOP), Thin Quad Flat Pack (TQFP), System In Package (SIP), Multi-Chip Package (MCP), Wafer-level Fabricated Package (WFP), or Wafer-level processed Stack Package (WSP).

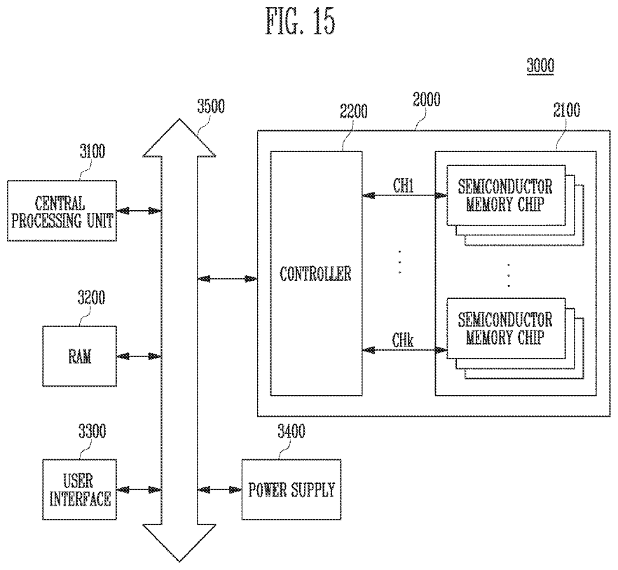

FIG. 14 is a block diagram illustrating an application example 2000 of the memory system of FIG. 1

Referring to FIG. 14, the memory system 2000 includes a semiconductor memory device 2100 and a controller 2200. The semiconductor memory device 2100 includes a plurality of semiconductor memory chips. The plurality of semiconductor memory chips are divided into a plurality of groups.

FIG. 14 illustrates that the plurality of groups communicate with the controller 2200 through first to kth channels CH1 to CHk. Each semiconductor memory chip may be configured and operated identically to the semiconductor memory device 1300 described with reference to FIG. 13.

Each group is configured to communicate with the controller 2200 through one common channel. The controller 2200 is configured identically to the controller 1200 described with reference to FIG. 13. The controller 2200 is configured to control the plurality of memory chips of the semiconductor memory device 2100 through the plurality of channels CH1 to CHk.

In FIG. 14, a case where a plurality of semiconductor memory chips are coupled to one channel is described. However, it will be understood that the memory system 2000 may be modified such that one semiconductor memory chip is coupled to one channel.

FIG. 15 is a block diagram illustrating a computing system including the memory system described with reference to FIG. 14.

Referring to FIG. 15, the computing system 3000 includes a central processing unit 3100, a RAM 3200, a user interface 3300, a power supply 3400, a system bus 3500, and a memory system 2000.

The memory system 2000 is electrically coupled to the central processing unit 3100, the RAM 3200, the user interface 3300, and the power supply 3400 through the system bus 3500. Data supplied through user interface 3300 or data processed by the central processing unit 3100 are stored in the memory system 2000.

FIG. 15 illustrates that the semiconductor memory device 2100 is coupled to the system bus 3500 through the controller 2200. However, the semiconductor memory device 2100 may be directly coupled to the system bus 3500. The function of the controller 2200 may be performed by the central processing unit 3100 and the RAM 3200.

FIG. 15 illustrates that the memory system 2000 described with reference to FIG. 14 is provided. However, the memory system 2000 may be replaced by the memory system 1000 described with reference to

FIG. 13. In an embodiment, the computing system 3000 may be configured to include both of the memory systems 1000 and 2000 described with reference to FIGS. 13 and 14.

According to the present disclosure, there can be provided a semiconductor memory device having improved reliability and an operating method thereof.

While the present disclosure has been shown and described with reference to certain exemplary embodiments thereof, it will be understood by those skilled in the art that various changes in form and details may be made therein without departing from the spirit and scope of the present disclosure as defined by the appended claims and their equivalents. Therefore, the scope of the present disclosure should not be limited to the above-described exemplary embodiments but should be determined by not only the appended claims but also the equivalents thereof.

In the above-described embodiments, all steps may be selectively performed or part of the steps and may be omitted. In each embodiment, the steps are not necessarily performed in accordance with the described order and may be rearranged. The embodiments disclosed in this specification and drawings are only examples to facilitate an understanding of the present disclosure, and the present disclosure is not limited thereto. That is, it should be apparent to those skilled in the art that various modifications can be made on the basis of the technological scope of the present disclosure.

Meanwhile, the exemplary embodiments of the present disclosure have been described in the drawings and specification. Although specific terminologies are used here, those are only to explain the embodiments of the present disclosure. Therefore, the present to disclosure is not restricted to the above-described embodiments and many variations are possible within the spirit and scope of the present disclosure. It should be apparent to those skilled in the art that various modifications can be made on the basis of the technological scope of the present disclosure in addition to the embodiments disclosed herein.

What is claimed is:

1. A semiconductor memory device comprising
a memory cell array including a plurality of memory cells;
a peripheral circuit configured to perform an operation on the memory cell array;
a control logic configured to control an operation of the peripheral circuit, and generate a ready-busy signal representing whether the operation of the peripheral circuit is completed; and
a temperature sensor configured to measure a temperature of the semiconductor memory device,
wherein the control logic generates the ready-busy signal, based on the temperature.

2. The semiconductor memory device of claim 1, wherein, when the temperature is higher than a predetermined reference temperature, the control logic provides a dummy busy time to generate the ready-busy signal.

3. The semiconductor memory device of claim 2, wherein the control logic maintains a busy state of the ready-busy signal during the dummy busy time after the operation of the peripheral circuit is completed.

4. The semiconductor memory device of claim 3, wherein the control logic includes a ready-busy signal generator having:
a reference temperature storage configured to the reference temperature;
a dummy busy determiner configured to generate a dummy busy activation signal by comparing the temperature and the reference temperature; and
a signal generator configured to generate the ready-busy signal, based on the dummy busy activation signal.

5. The semiconductor memory device of claim 4, wherein the dummy busy determiner:
enables the dummy busy activation signal when the temperature is higher than the reference temperature; and
disables the dummy busy activation signal when the temperature is equal to or lower than the reference temperature.

6. The semiconductor memory device of claim 5, wherein the signal generator changes, when the dummy busy activation signal is enabled, the state of the ready-busy signal to a ready state after the signal generator stands by for the dummy busy time from the time at which the operation of the peripheral circuit is completed.

7. The semiconductor memory device of claim 5, wherein the signal generator changes, when the dummy busy activation signal is disabled, the state of the ready-busy signal to the ready state at the time at which the operation of the peripheral circuit is completed.

8. The semiconductor memory device of claim 3, wherein the control logic includes a ready-busy signal generator having:
a reference temperature storage configured to store a dummy busy table including a plurality of reference temperature ranges and respectively corresponding dummy busy times;
a dummy busy determiner configured to generate a dummy busy activation signal by comparing the temperature with the dummy busy table; and
a signal generator configured to generate the ready-busy signal, based on the dummy busy activation signal.

9. A method for operating a semiconductor memory device, the method comprising:
receiving an operation command from a controller;
performing an operation corresponding to the received operation command; and
controlling a ready-busy signal output from the semiconductor memory device to the controller according to a temperature of the semiconductor memory device.

10. The method of claim 9, wherein the ready-busy signal maintains a busy state during the operation.

11. The method of claim 10, wherein the controlling of the ready-busy signal includes:
checking a temperature of the semiconductor memory device;
comparing the temperature with a predetermined reference temperature; and
controlling the ready-busy signal, based on the comparison result.

12. The method of claim 11, wherein the controlling of the ready-busy signal based on the comparison result, includes:
standing by, when the temperature is higher than the reference temperature, for a predetermined dummy busy time; and
changing the state of the ready-busy signal from the busy state to a ready state after the predetermined dummy busy time.

13. The method of claim 11, wherein the controlling of the ready-busy signal, based on the comparison result, includes:
changing, when the temperature is equal to or lower than the reference temperature, the state of the ready-busy signal from the busy state to the ready state.

14. The method of claim 10, wherein the controlling of the ready-busy signal includes:
checking a temperature of the semiconductor memory device;
comparing the temperature with a predetermined dummy busy table; and
controlling the ready-busy signal, based on the comparison result.

15. The method of claim 14, wherein the dummy busy table includes a plurality of reference temperature ranges and respectively corresponding dummy busy times.

16. The method of claim 15, wherein the controlling of the ready-busy signal based on the comparison result includes changing the state of the ready-busy signal from the busy state to the ready state after a dummy busy time corresponding to a reference temperature section to which the temperature of the semiconductor memory device belongs.

17. The method of claim 9, wherein the operation command is a program command.

18. The method of claim 9, wherein the operation command is an erase command.

19. A memory device for performing a data operation in response to a command from a controller, the memory device comprising:
a sensor configured to measure a temperature of the memory device during the data operation; and
a control logic configured to provide the controller with a busy signal during the data operation and with a ready signal upon completion of the data operation,
wherein the control logic provides, when the temperature is higher than a threshold, the controller with the busy signal instead of the ready signal for a predetermined time even after the completion.
